(19) United States
(12) Patent Application Publication
(10) Pub. No.: US 2018/0190848 A1
(43) Pub. Date: Jul. 5, 2018

(54) WAVELENGTH CONVERSION FILTER, MANUFACTURING METHOD THEREOF, AND SOLAR CELL MODULE

(71) Applicant: Panasonic Intellectual Property Management Co., Ltd., Osaka (JP)

(72) Inventors: Yoshimitsu IKOMA, Nara (JP); Natsuki SATO, Osaka (JP)

(21) Appl. No.: 15/739,737

(22) PCT Filed: Aug. 10, 2016
(86) PCT No.: PCT/JP2016/003711

§ 371 Date: Dec. 24, 2017

(30) Foreign Application Priority Data
Aug. 19, 2015 (JP) 2015-161880
Mar. 11, 2016 (JP) 2016-047729

(51) Int. Cl. H01L 31/055; C09K 11/02

(52) U.S. Cl. CPC H01L 31/055; C09K 11/02

(57) ABSTRACT

A wavelength conversion filter, includes: a wavelength conversion layer in which a wavelength conversion material is dispersed in a transparent resin base material; and an ultraviolet absorption layer which is provided on the surface of the wavelength conversion layer and in which an ultraviolet absorber is dispersed in a transparent resin base material, wherein the wavelength conversion layer contains 0.01 to 30 parts by mass of the wavelength conversion material with respect to 100 parts by mass of the transparent resin base material included in the wavelength conversion layer.

### TECHNICAL FIELD

The present invention relates to a wavelength conversion technique and specifically relates to a wavelength conversion filter which performs wavelength conversion for light having an excitation wavelength, a method of manufacturing the same, and a solar cell module including the same.

### BACKGROUND ART

Solar cell modules generally convert only a part of sunlight that has certain wavelengths, to electricity, resulting in low photoelectric conversion efficiency. Accordingly, there has been a wavelength conversion technique that increases the photoelectric conversion efficiency by converting light with wavelengths that cannot be used in a solar cell module to light with wavelengths that can be used. Moreover, solar cell modules are often used outdoors and therefore need to have very high durability.

Patent Literature 1 discloses a wavelength conversion filter which uses two types of inorganic wavelength conversion materials. Patent Literature 2 discloses a two-layer wavelength conversion filter including: a sealing layer containing a wavelength conversion material; and a sealing layer containing 2,2′-dihydroxy-4,4′-dimethoxybenzophenone as an ultraviolet absorber.

### CITATION LIST

### Patent Literature

Patent Literature 1: Japanese Unexamined Patent Application Publication No. 2004-161841

Patent Literature 2: Japanese Unexamined Patent Application Publication No. 2014-232792

### SUMMARY OF INVENTION

### Technical Problem

However, since the wavelength conversion filter disclosed in Patent Literature 1 uses inorganic wavelength conversion materials, the wavelength conversion filter is excellent in durability but is not able to sufficiently filter out ultraviolet light. The inorganic wavelength conversion materials have low ultraviolet absorption coefficients. It is therefore likely to be difficult for the inorganic wavelength conversion materials to filter out ultraviolet light if the grain size thereof is large. In the wavelength conversion filter disclosed in Patent Literature 2,2,2′-dihydroxy-4,4′-dimethoxybenzophenone as the ultraviolet absorber diffuses in the sealing material layer and enters the sealing layer containing the wavelength conversion material, reducing the light transmission efficiency.

The present invention was made in the light of the aforementioned problems. An object of the present invention is to provide a wavelength conversion filter capable of maintaining a high efficiency of wavelength conversion from ultraviolet light to visible light for a long time and a method of manufacturing the wavelength conversion filter. Another object of the present invention is to provide a solar cell module in which the wavelength conversion filter maintains the high efficiency of wavelength conversion from ultraviolet light to visible light for a long time.

### Solution to Problem

To solve the aforementioned problem, a wavelength conversion filter according to an aspect of the present invention includes: a wavelength conversion layer in which a wavelength conversion material is dispersed in a transparent resin base material; and an ultraviolet absorption layer which is provided on the surface of the wavelength conversion layer and in which an ultraviolet absorber is dispersed in a transparent resin base material. The wavelength conversion layer contains 0.01 to 30 parts by mass of the wavelength conversion material with respect to 100 parts by mass of the transparent resin base material included in the wavelength conversion layer.

A solar cell module according to another aspect of the present invention includes: the wavelength conversion filter; and a surface protection sheet which is provided on the side of the wavelength conversion layer constituting the wavelength conversion filter. The solar cell module according to the another aspect of the present invention further includes a solar cell which is provided on the side of the ultraviolet absorption layer constituting the wavelength conversion filter and generates electric power with visible light having passed through the wavelength conversion filter.

A method of manufacturing a wavelength conversion filter according to still another aspect of the present invention is a method of manufacturing the wavelength conversion filter. The method of manufacturing a wavelength conversion filter combines the reactive ultraviolet absorber with the molecular backbone of the transparent resin base material included in the ultraviolet absorption layer to form an ultraviolet absorption layer containing an unreactive ultraviolet absorber.

### BRIEF DESCRIPTION OF DRAWINGS

FIG. 1 is a cross-sectional view schematically illustrating an example of a solar cell module according to an embodiment.

### DESCRIPTION OF EMBODIMENTS

Hereinafter, a description is given of a solar cell module according to an embodiment, a wavelength conversion filter constituting the solar cell module, and a wavelength conversion material contained in the wavelength conversion filter with reference to the drawings.

### [Solar Cell Module]

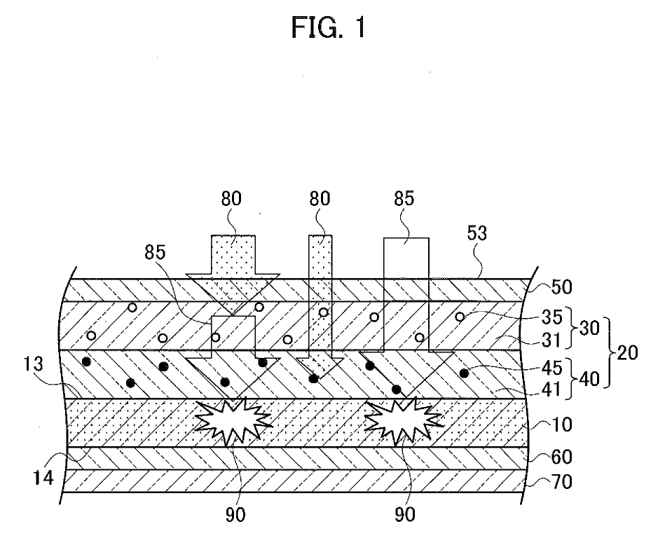

FIG. 1 is a cross-sectional view schematically illustrating an example of the solar cell module according to the embodiment. As illustrated in FIG. 1, a solar cell module 1 includes: a solar cell 10; a wavelength conversion filter 20 provided on a light receiving surface 13 side of the solar cell 10; and a surface protection sheet 50 provided on a surface of the wavelength conversion filter 20. The wavelength conversion filter 20 has a two-layer structure composed of: a wavelength conversion layer 30 in which a wavelength conversion material 35 is dispersed in a transparent resin base material 31; and an ultraviolet absorption layer 40 which is provided on the surface of the wavelength conversion layer 30 on the solar cell 10 side and in which an ultraviolet absorber 45 is dispersed in a transparent resin base material 41.

The solar cell module 1 includes: the wavelength conversion filter 20; and the surface protection sheet 50 which is provided on the side of the wavelength conversion layer 30 constituting the wavelength conversion filter 20, and is configured to protect the surface of the wavelength conversion layer 30. The solar cell module 1 further includes: the solar cell module 10, which is provided on the side of the ultraviolet absorption layer 40 constituting the wavelength conversion filter 20, and is configured to generate electricity with visible light having passed through the wavelength conversion filter 20.

The solar cell module 1 further includes: a back surface sealing member 60, which is provided on a back surface 14; and a back surface protection sheet 70, which is provided on the back surface of the back surface sealing member 60. The back surface 14 is one of the surfaces of the solar cell 10 opposite to the light receiving surface 13. In other words, the solar cell module 1 includes the surface protection sheet 50, wavelength conversion filter 20, solar cell 10, back surface sealing member 60, and back surface protection sheet 70, which are provided in this order from the top in the view. The solar cell module 1 is configured to generate photovoltaic power in such a manner that light entering the solar cell module 1 through a light incoming surface 53, which is the surface of the surface protection sheet 50, is received by the solar cell 10 directly or after converted in the wavelength conversion filter 20. Hereinafter, each component is described in detail.

### (Solar Cell)

The solar cell 10 absorbs light entering through the light receiving surface 13 of the solar cell 10 and generates photovoltaic power. The solar cell 10 is made of a semiconductor material such as crystalline silicon, gallium arsenide (GaAs), or indium phosphide (InP), for example. Specifically, the solar cell 10 is composed of a laminate of crystalline silicon and amorphous silicon, for example. Not-illustrated electrodes are provided for the light receiving surface 13 of the solar cell 10 and the back surface 14, which is opposite to the light receiving surface 13. The photovoltaic power generated by the solar cell 10 is supplied to the outside through the electrodes.

### (Wavelength Conversion Filter)

The wavelength conversion filter 20 is provided on the light receiving surface 13 side of the solar cell 10. As illustrated in FIG. 1, the wavelength conversion filter 20 has a two-layer structure composed of the wavelength conversion layer 30 and the ultraviolet absorption layer 40, which is provided on the surface of the wavelength conversion layer 30 on the solar cell 10 side.

<Wavelength Conversion Layer>

The wavelength conversion layer 30 is a layer in which the wavelength conversion material 35 is dispersed in the transparent resin base material 31. In the wavelength conversion layer 30, the wavelength conversion material 35 has a function of converting received ultraviolet light 80 to visible light 85, which has longer wavelengths.

The transparent resin base material 31 is transparent resin which keeps the wavelength conversion material 35 dispersed and conducts the received ultraviolet light 80 to the wavelength conversion material 35. The transparent resin constituting the transparent resin base material 31 is transparent resin such as ethylene-vinyl acetate copolymer (EVA), (meth)acrylic resin, polyvinyl butyral (PVB), polyimide, polyethylene, polypropylene, or polyethylene terephthalate (PET), for example.

The wavelength conversion material 35 is inorganic phosphor or organic phosphor, for example. The inorganic phosphor is preferred because of high durability and high moisture resistance thereof. The durability means that the composition and crystalline structure of the inorganic phosphor do not change or are less likely to change with time.

Inorganic phosphors generally have a crystalline structure in which some of the atoms constituting the host crystal composed of an inorganic compound are partially substituted with luminescence centers that emit fluorescence. The inorganic phosphor used in the embodiment is not particularly limited. The inorganic phosphor used in the embodiment is CaF₂:Eu, for example. CaF₂:Eu indicates that CaF₂ is the host crystal and Eu is luminescence centers.

The organic phosphor is a naphthalimide compound, a perylene compound, or the like. Examples of commercialized products of the organic phosphor are Lumogen (registered trademark) F violet 570 (naphthalimide compound), Lumogen F yellow 083 (perylene compound), and Lumogen F yellow 170 (perylene compound).

The phosphor preferably absorbs ultraviolet light with wavelengths of 400 nm or shorter and performs wavelength conversion for the absorbed ultraviolet light to green to near-infrared light with wavelengths of 400 to 1100 nm. It is preferable if the phosphor has such characteristics because light supplied through the wavelength conversion filter to the solar cell contains more wavelength components that allow for high photoelectric conversion efficiency in the solar cell. The phosphor is preferably a phosphor efficiently excited by light with a wavelength of 300 nm or more at which the intensity of the solar spectrum is relatively high. This is because when the phosphor has such a characteristics, a large amount of light is supplied from the wavelength conversion filter to the solar cell.

[Form]

The wavelength conversion material 35 is preferably in granular or powder form. When the wavelength conversion material is in granular or powder form, the wavelength conversion material 35 easily disperses in the transparent resin base material 31. When the wavelength conversion material is in granular or powder form, the average particle size thereof is typically not less than 0.1 μm and less than 100 μm, preferably not less than 0.3 μm and less than 30 Ξm, and more preferably not less than 1 μm and less than 10 μm. When the wavelength conversion member is made of the wavelength conversion material having an average particle size in the aforementioned ranges, the wavelength conversion member absorbs ultraviolet light sufficiently and has a visible light transmittance prevented from being reduced. The average particle size of the wavelength conversion material can be measured by observing a cross section of the wavelength conversion member with a scanning electron microscope. For example, the average particle size is defined as the average of the maximum axis length of 20 or more arbitrary particles of the wavelength conversion material.

[Mixing Ratio of Transparent Resin Base Material and Wavelength Conversion Material]

The wavelength conversion layer 30 contains, with respect to 100 parts by mass of the transparent resin base material contained in the wavelength conversion layer, 0.01 to 30 parts by mass of the wavelength conversion material, preferably 0.1 to 20 parts by mass, and more preferably 1 to 10 parts by mass. When the mixing ratio of the wavelength conversion material to the transparent resin base material in the wavelength conversion layer 30 is less than 0.01 parts by mass, the wavelength conversion function of the wavelength conversion material could not be exerted sufficiently. When the mixing ratio of the wavelength conversion material to the transparent resin base material in the wavelength conversion layer 30 is more than 30 parts by mass, the light transmittance of the wavelength conversion layer 30 could be reduced.

[Thickness of Wavelength Conversion Layer]

The thickness of the wavelength conversion layer 30 is not particularly limited and is 10 to 10000 μm, for example. It is preferable that the thickness of the wavelength conversion layer 30 is in this range because the conversion from ultraviolet light incident on the wavelength conversion layer 30 to visible light is performed efficiently while the wavelength conversion layer 30 is made thin.

[Manufacturing Method of Wavelength Conversion Layer]

The wavelength conversion layer 30 is produced by mixing the phosphor 35 with the transparent resin base material 31 to disperse the phosphor 35 in the transparent resin base material 31 and shaping the mixture into a sheet, a film, a plate, or another form.

<Ultraviolet Absorption Layer>

The ultraviolet absorption layer 40 is a layer in which the ultraviolet absorber 45 is dispersed in the transparent resin base material 41. In the ultraviolet absorption layer 40, the ultraviolet absorber 45 has a function of absorbing the received ultraviolet light 80.

The transparent resin base material 41 is a transparent resin that keeps the ultraviolet absorber 45 dispersed and conducts the received ultraviolet light 80 to the ultraviolet absorber 45. The transparent resin constituting the transparent resin base material 41 can be the same as that of the transparent resin base material 31. Specifically, the transparent resin base material 41 is transparent resin such as ethylene-vinyl acetate copolymer (EVA), (meth)acrylic resin, polyvinyl butyral (PVB), polyimide, polyethylene, polypropylene, or polyethylene terephthalate (PET), for example.

The ultraviolet absorber 45 is an organic ultraviolet absorber or an inorganic ultraviolet absorber, for example.

[Organic Ultraviolet Absorber]

The organic ultraviolet absorber is a reactive ultraviolet absorber or an unreactive ultraviolet absorber, for example. The reactive ultraviolet absorber refers to an ultraviolet absorber which includes an ultraviolet absorption part having a molecular structure for absorbing ultraviolet light and has a function of combining with the molecular backbone of the transparent resin base material 41 included in the ultraviolet absorption layer 40. In other words, in addition to the ultraviolet absorption part, the reactive ultraviolet absorber includes a transparent resin joint part having a molecular structure that can combine with the molecular backbone of the transparent resin base material 41. As described later, the transparent resin joint part combines with the molecular backbone of the transparent resin base material 41 due to radical polymerization, cationic polymerization, anionic polymerization, or the like upon exposure to heat or light. By the transparent resin joint part combining with the molecular backbone of the transparent resin base material 41 contained in the ultraviolet absorption layer 40, the reactive ultraviolet absorber is incorporated in the molecular backbone of the transparent resin base material 41. When the reactive ultraviolet absorber is incorporated in the molecular backbone of the transparent resin base material 41 contained in the ultraviolet absorption layer 40, the reactive ultraviolet absorber is less likely to diffuse in the transparent resin base material 41 contained in the ultraviolet absorption layer 40.

When the reactive ultraviolet absorber is mixed with the transparent resin base material 41 and is then exposed to light or heat, for example, the transparent resin joint part combines with the molecular backbone of the transparent resin base material 41 due to radical polymerization, cationic polymerization, or anionic polymerization. When the reactive ultraviolet absorber combines with the molecular backbone of the transparent resin base material 41 contained in the ultraviolet absorption layer 40, the resultant substance includes the molecular backbone of the transparent resin base material 41 and the ultraviolet absorption part. Accordingly, the substance obtained by combining the reactive ultraviolet absorber and the molecular backbone of the transparent resin base material 41 is a substance having the same or similar structure to that of the later-described unreactive ultraviolet absorber. In FIG. 1, reference numeral 45 indicates the organic ultraviolet absorber such as the reactive or unreactive ultraviolet absorber or the inorganic ultraviolet absorber. Among these absorbers, the later-described unreactive ultraviolet absorber and inorganic ultraviolet absorber do not change the molecular structure even in the transparent resin base material 41. It is therefore proper that the ultraviolet absorber is indicated by reference numeral 45. However, the reactive ultraviolet absorber changes the molecular structure when combining with the molecular backbone of the transparent resin base material 41 by radical polymerization, cationic polymerization, and anionic polymerization as described above. Accordingly, when the ultraviolet absorber is the reactive ultraviolet absorber, the reference numeral 45 in FIG. 1 indicates the reactive ultraviolet absorber before combining with the molecular backbone of the transparent resin base material 41.

The ultraviolet absorption part of the reactive ultraviolet absorber includes one or more types of structure selected from a group consisting of a benzotriazole structure, a triazine structure, and a benzophenone structure. The benzotriazole structure refers to the backbone part of benzotriazole and specifically refers to the backbone part of benzotriazole C₆H₅N₃ with H removed. The triazine structure refers to the backbone part of triazine and specifically refers to a backbone part of triazine C₉H₅Cl₃N₄ with H removed. The benzophenone structure refers to the backbone part of benzophenone and specifically refers to the backbone part of benzophenone Cl₃H₁₀O with H removed.

In addition to the aforementioned ultraviolet absorption part, the reactive ultraviolet absorber includes the transparent resin joint part to combine with the molecular backbone of the transparent resin base material 41. The transparent resin joint part is a functional group such as a glycidyl group, a vinyl group, or a silanol group, for example. It is preferable that the reactive ultraviolet absorber includes such a functional group because the reactive ultraviolet absorber including such a functional group is more likely to combine with the molecular backbone of the transparent resin base material 41 contained in the ultraviolet absorption layer 40 to be incorporated in the molecular backbone of the transparent resin base material 41.

The reactive ultraviolet absorber may further include a structure including a transparent resin backbone structure that can combine with the ultraviolet absorption part, a side chain that can combine with the ultraviolet absorption part, or the like in addition to the aforementioned ultraviolet absorption part. Moreover, the reactive ultraviolet absorber may have a structure including a transparent resin backbone structure that can combine with the ultraviolet absorption part, a side chain that can combine with the ultraviolet absorption part, or the like in addition to the aforementioned ultraviolet absorption part and transparent resin joint part. Herein, the transparent resin backbone structure refers to a backbone structure composed of all or a part of the molecular backbone of the transparent resin base material 41 contained in the ultraviolet absorption layer 40. When the molecular backbone of the transparent resin base material 41 is (meth)acrylic resin, for example, the transparent resin backbone structure is —(C—C)n-COO— (n is a natural number) composed of a part of the molecular backbone of (meth)acrylic resin. When the molecular backbone of the transparent resin base material 41 is ethylene-vinyl acetate copolymer (EVA), for example, the transparent resin backbone structure is —(C—C)n-OCOCH₃— (n is a natural number) composed of a part of the molecular backbone of EVA. Hereinafter, the backbone structures of ethylene-vinyl acetate copolymer, (meth)acrylic resin, and polyolefin are referred to as an ethylene-vinyl acetate copolymer backbone structure, a (meth)acrylic resin backbone structure, and a polyolefin backbone structure, respectively.

The transparent resin backbone structure of the reactive ultraviolet absorber contained in the ultraviolet absorption layer 40 is preferably the same as all or a part of the molecular backbone of the transparent resin base material 41 contained in the ultraviolet absorption layer 40. When the transparent resin base material 41 contained in the ultraviolet absorption layer 40 is (meth)acrylic resin, for example, the reactive ultraviolet absorber contained in the ultraviolet absorption layer 40 preferably includes the (meth)acrylic resin backbone structure. In a similar manner, when the transparent resin base material 41 contained in the ultraviolet absorption layer 40 is ethylene-vinyl acetate copolymer, for example, the reactive ultraviolet absorber contained in the ultraviolet absorption layer 40 preferably includes the ethylene-vinyl acetate copolymer backbone structure. Moreover, the side chain that can combine with the ultraviolet absorption part of the reactive ultraviolet absorber is an alkyl group such as a methyl group or an ethyl group, for example.

As the reactive ultraviolet absorber, the following substances are used, for example. Specifically, the reactive ultraviolet absorber is a compound including the (meth)acrylic resin backbone structure and benzotriazole structure in a molecule, a compound including the ethylene-vinyl acetate copolymer backbone structure and benzotriazole structure in a molecule, or a compound including the polyolefin backbone structure and benzotriazole structure in a molecule. Moreover, the reactive ultraviolet absorber is a compound including the (meth)acrylic resin backbone structure and triazine structure in a molecule, a compound including the ethylene-vinyl acetate copolymer backbone structure and triazine structure in a molecule, or a compound including the polyolefin backbone structure and triazine structure in a molecule. Furthermore, the reactive ultraviolet absorber is a compound including the (meth)acrylic resin backbone structure and benzophenone structure in a molecule, a compound including the ethylene-vinyl acetate copolymer backbone structure and benzophenone structure in a molecule, or a compound including the polyolefin backbone structure and benzophenone structure in a molecule.

In the case of using the reactive ultraviolet absorber, a cross-linking agent that can react with the reactive ultraviolet absorber may be used together. Using the reactive ultraviolet absorber and cross-linking agent in combination facilitates polymerization of the reactive ultraviolet absorber, so that the reactive ultraviolet absorber is less likely to diffuse. The cross-linking agent is difunctional methacrylate or polyfunctional methacrylate, for example. These difunctional methacrylate and polyfunctional methacrylate are useful as the cross-linking agent for the reactive ultraviolet absorber including a vinyl group. Examples of commercialized products of the cross-linking agent are ethylene glycol dimethacrylate (by Shin-Nakamura Chemical Co., Ltd.), diethylene glycol dimethacrylate, polyethylene glycol #400 dimethacrylate, and trimethylolpropane trimethacrylate.

The unreactive ultraviolet absorber refers to an ultraviolet absorber including the molecular backbone of transparent resin and the ultraviolet absorption part having a molecular structure for combining with the molecular backbone of the transparent resin and absorbing ultraviolet light. Herein, the ultraviolet absorption part is the same as the ultraviolet absorption part of the reactive ultraviolet absorber and has one or more types of structure selected from a group consisting of a benzotriazole structure, a triazine structure, and a benzophenone structure. The transparent resin constituting a part of the unreactive ultraviolet absorber is not particularly limited but needs to be transparent resin. The transparent resin constituting a part of the unreactive ultraviolet absorber is the same as the transparent resin used in the transparent resin base material 41, for example. Specifically, the transparent resin constituting a part of the unreactive ultraviolet absorber is transparent resin such as ethylene-vinyl acetate copolymer (EVA), polyvinyl butyral (PVB), polyimide, polyethylene, polypropylene, or polyethylene terephthalate (PET), for example.

As the unreactive ultraviolet absorber, the following substances are used, for example. Specifically, the unreactive ultraviolet absorber is (meth)acrylate copolymer including the benzotriazole structure in a side chain, ethylene-vinyl acetate copolymer including the benzotriazole structure in a side chain, and polyolefin including the benzotriazole structure in a side chain. Moreover, the unreactive ultraviolet absorber is (meth)acrylate copolymer including the triazine structure in a side chain, ethylene-vinyl acetate copolymer including the triazine structure in a side chain, and polyolefin including the triazine structure in a side chain. Furthermore, the unreactive ultraviolet absorber is a (meth)acrylate copolymer including the benzophenone structure in a side chain, ethylene-vinyl acetate copolymer including the benzophenone structure in a side chain, and polyolefin including the benzophenone structure in a side chain.

The unreactive ultraviolet absorber typically has a molecular weight of typically not less than 5000 and preferably not less than 10000. Moreover, the unreactive ultraviolet absorber has a molecular weight of typically not more than 100000 and preferably not more than 50000. When the molecular weight of the unreactive ultraviolet absorber is in the aforementioned range, the unreactive ultraviolet absorber having such a molecular weight is less likely to diffuse in the transparent resin base material 41 contained in the ultraviolet absorption layer 40. It is not preferable if the molecular weight of the unreactive ultraviolet absorber is less than 5000 because the unreactive ultraviolet absorber in the ultraviolet absorption layer 40 diffuses in the transparent resin base material 41 and moves to the wavelength conversion layer 30, so that ultraviolet light is absorbed by the unreactive ultraviolet absorber in the wavelength conversion layer 30. On the other hand, it is not preferable if the molecular weight of the unreactive ultraviolet absorber exceeds 100000 because it is difficult to mix the unreactive ultraviolet absorber having such a molecular weight and the transparent resin base material 41.

[Inorganic Ultraviolet Absorber]

Examples of the inorganic ultraviolet absorber are nanoparticles of a metal oxide such as zinc oxide ZnO, cerium oxide CeO₂, and titanium oxide TiO₂. Herein, the nanoparticles refer to particles having an average particle size of less than 100 nm.

[Mixing Ratio of Transparent Resin Base Material and Ultraviolet Absorber]

The ultraviolet absorption layer 40 contains, with respect to 100 parts by mass of the transparent resin base material, typically 0.001 to 5 parts by mass of the ultraviolet absorber 45, preferably 0.005 to 3 parts by mass, and more preferably 0.01 to 1 parts by mass. When the content of the ultraviolet absorber is within the aforementioned range, the ultraviolet light incident on the ultraviolet absorption layer 40 is absorbed at high efficiency. When the content of the ultraviolet absorber is less than 0.001 parts by mass, the ultraviolet absorption function is insufficient. If the content of the ultraviolet absorber is more than 1 parts by mass, the ultraviolet absorption function cannot increase any more, which is not cost-efficient.

[Manufacturing Method of Ultraviolet Absorption Layer]

When the ultraviolet absorber 45 is the organic unreactive ultraviolet absorber or inorganic ultraviolet absorber, the ultraviolet absorption layer 40 is produced by mixing the ultraviolet absorber 45 with the transparent resin base material 41 to disperse the ultraviolet absorber 45 in the transparent resin base material 41 and shaping the absorber-dispersed product into a sheet, a film, a plate, or another form.

When the ultraviolet absorber 45 is the organic reactive ultraviolet absorber, the ultraviolet absorption layer 40 including a substance of the same or similar structure as that of the unreactive ultraviolet absorber is produced in the following manner. Herein, the same or similar structure as that of the unreactive ultraviolet absorber indicates that the ultraviolet absorber includes the molecular backbone of the transparent resin base material 41 and the ultraviolet absorption part.

First, the ultraviolet absorber 45 and the transparent resin base material 41 are mixed in order to disperse the ultraviolet absorber 45 in the transparent resin base material 41. Next, the reactive ultraviolet absorber 45 is caused to combine with the molecular backbone of the transparent resin base material 41 contained in the ultraviolet absorption layer 40, so that the ultraviolet absorber of the same or similar structure as that of the unreactive ultraviolet absorber is formed in the ultraviolet absorber layer 40. The reactive ultraviolet absorber 45 is combined with the molecular backbone of the transparent resin base material 41 contained in the ultraviolet absorption layer 40 by applying light or heat to the reactive ultraviolet absorber 45 and transparent resin base material 41 to induce radical polymerization, cationic polymerization, and anionic polymerization.

<Manufacturing Method of Wavelength Conversion Filter>

The wavelength conversion filter 20 according to the embodiment is manufactured by thermally fusing the wavelength conversion layer 30 obtained by the aforementioned method of manufacturing a wavelength conversion layer and the ultraviolet absorption layer 40 obtained by the aforementioned method of manufacturing an ultraviolet absorption layer, for example. The method of manufacturing a wavelength conversion filter according to the embodiment can therefore include the aforementioned method of manufacturing an ultraviolet absorption layer. When the ultraviolet absorber 45 is an organic reactive ultraviolet absorber, an example of the method of manufacturing the wavelength conversion filter according to the embodiment is shown below. Specifically, in the method of manufacturing the wavelength conversion filter according to the embodiment, the reactive ultraviolet absorber is caused to combine with the molecular backbone of the transparent resin base material 41 contained in the ultraviolet absorption layer 40, so that the ultraviolet absorber of the same of similar structure as that of the unreactive ultraviolet absorber is formed.

<Operation of Wavelength Conversion Filter>

Using FIG. 1, a description is given of an operation of the wavelength conversion filter 20. When the solar cell module 1 is exposed to sunlight containing the ultraviolet light 80 and visible light 85, the ultraviolet light 80 and visible light 85 enter the surface protection sheet 50 through the light incoming surface 53 to pass through the same and then enter the wavelength conversion layer 30 of the wavelength conversion filter 20. The visible light 85 having entered the wavelength conversion layer 30 of the wavelength conversion filter 20 is not substantially subjected to wavelength conversion by the wavelength conversion material 35 and sequentially passes through the wavelength conversion layer 30 and ultraviolet absorption layer 40 of the wavelength conversion filter 20 to be directly projected onto the solar cell 10. On the other hand, the ultraviolet light 80 having entered the wavelength conversion layer 30 of the wavelength conversion filter 20 is converted to the visible light 85 having longer wavelengths by the wavelength conversion material 35 to be projected onto the solar cell 10. Part of the ultraviolet light 80 which has entered the wavelength conversion layer 30 and has passed through the same without being converted to the visible light 85 is absorbed by the ultraviolet absorber 45 in the ultraviolet absorption layer 40. Accordingly, the light passing through the ultraviolet absorption layer 40 of the wavelength conversion filter 20 is substantially only the visible light 85. The solar cell 10 produces photovoltaic power 90 with the visible light 85 having passed through the wavelength conversion filter 20, and the photovoltaic power 90 is then supplied to the outside of the solar cell module 1 through a not-illustrated terminal. The ultraviolet light 80 is substantially not projected to the inside of the solar cell module 1 as described above, so that the solar cell module 1 is prevented from being damaged or deteriorated due to exposure to the ultraviolet light 80.

<Effect of Wavelength Conversion Filter>

With the wavelength conversion filter 20 used in the embodiment, the ultraviolet absorber 45 of the ultraviolet absorption layer 40 is incorporated in the molecular backbone of the transparent resin base material 41 and is therefore less likely to diffuse. This can maintain the two-layer structure of the wavelength conversion layer 30 and ultraviolet absorption layer 40 for a long time. According to the wavelength conversion filter 20, the efficiency of wavelength conversion from ultraviolet light to visible light is therefore less likely to be reduced due to diffusion of the ultraviolet absorber 45 and is maintained at a high level for a long time. The wavelength conversion filter 20 used in the embodiment is therefore suitable for the solar cell module 1.

### (Surface Protection Sheet)

The surface protection sheet 50 provided on the surface of the wavelength conversion filter 20 is configured to protect the wavelength conversion filter 20 and solar cell 10 from the external environment of the solar cell module 1. The surface protection sheet 50 may include a filter function to block light in a particular wavelength region if necessary. The surface protection sheet 50 is made of a glass substrate, polycarbonate, acryl, polyester, or polyethylene fluoride, for example.

### (Back Surface Sealing Member)

The back surface sealing member 60 provided on the back surface 14 of the solar cell 10 prevents water from entering the solar cell 10 and increases the strength of the entire solar cell module 1. The back surface sealing member 60 is composed of the same material as the material that can be used in the transparent resin base material 31 or 41 of the wavelength conversion filter 20, for example. The material of the back surface sealing member 60 may be the same or different from the material of the transparent resin base material 31 or 41 of the wavelength conversion filter 20.

### (Back Surface Protection Sheet)

The back surface protection sheet 70 provided on the back surface of the back surface sealing member 60 is configured to protect the back surface sealing member 60 and solar cell 10 from the external environment of the solar cell module 1. The back surface protection sheet 70 is composed of the same material as that can be used in the surface protection sheet 50, for example. The material of the back surface protection sheet 70 may be the same or different from the material of the surface protection sheet 50.

### (Operation of Solar Cell Module)

The operation of the solar cell module 1 is already described in the section about the operation of the wavelength conversion filter 20, and the description thereof is omitted.

### (Effect of Solar Cell Module)

With the solar cell module 1 according to the embodiment, the high efficiency of wavelength conversion from ultraviolet light to visible light by the wavelength conversion filter 20 is maintained for a long time. Moreover, with the solar cell module 1 according to the embodiment, the ultraviolet light 80 is not substantially projected to the inside of the solar cell module 1, so that the solar cell module 1 is prevented from being damaged or deteriorated due to exposure to the ultraviolet light 80.

### EXAMPLES

Hereinafter, the embodiment is described in more detail using examples. The embodiment is not limited to the examples.

A calcium fluoride phosphor was synthesized by a preparation method using solid-phase reaction, and the characteristics thereof were evaluated.

In the examples, powder of the following compounds was used as the raw materials.

calcium fluoride (CaF₂): 3N purity, made by KOJUNDO CHEMICAL LABORATORY, CO., LTD.

europium fluoride (EuF₃): 3N purity, made by Wako Pure Chemical Industries, Ltd.

### Example 1

### (Phosphor)

First, the raw materials were weighed to proportions that could provide a phosphor having a composition of Ca_{0.99}F₂Eu_{0.01}. Next, the raw materials were dry-mixed sufficiently using a magnetic mortar and a magnetic pestle to produce a baking raw material. The baking raw material was moved to an alumina crucible and was baked at a temperature of 850° C. under a reducing atmosphere (96% nitrogen and 4% hydrogen gas mixture atmosphere) for two hours in a tubular atmosphere furnace. The baked product was disintegrated using an alumina mortar and an alumina pestle, thus preparing the phosphor having a composition of Ca_{0.99}F₂Eu_{0.01}.

### (Wavelength Conversion Filter)

[Wavelength Conversion Layer]

18 parts by mass of the synthesized phosphor and 100 parts by mass of EVA (EVAFLEX (registered trademark) EV450 made by DU-PONT MITSUI POLYCHEMICALS) were melted and kneaded with a plastomill (made by TOYO SEIKI Co., Ltd.) at a heating temperature of 150° C. at 30 rpm for 30 minutes. The kneaded product is heat-pressed into a sheet with a thickness of 0.6 mm, thus preparing the wavelength conversion layer.

### [Ultraviolet Absorption Layer]

0.54 parts by mass of PUVA-50M-50K (molecular weight: 10000) (made by Daiwa Fine Chemicals Co., Ltd.) as the organic unreactive ultraviolet absorber and 100 parts by mass of EVA (EVAFLEX EV450 made by DU-PONT MITSUI POLYCHEMICALS) were prepared and were melted and kneaded with a plastomill (made by TOYO SEIKI Co., Ltd.) at a heating temperature of 150° C. at 30 rpm for 30 minutes. PUVA-50M-50K includes the molecular backbone of EVA and the ultraviolet absorption part of the benzotriazole structure. Next, the kneaded product was heat-pressed into a sheet with a thickness of 0.6 mm, thus preparing the ultraviolet absorption layer.

[Fusion of Wavelength Conversion Layer and Ultraviolet Absorption Layer]

The wavelength conversion layer and ultraviolet absorption layer were thermally fused at 100° C. into the wavelength conversion filter.

### (Measurement of External Quantum Efficiency and Absorptance)

The obtained wavelength conversion filter was measured in terms of the external quantum efficiency using a quantum efficiency measurement system QE-1100 made by OTSUKA ELECTRONICS Co., Ltd. The measurement and analysis conditions were as follows.

Excitation wavelength: 350 nm

Number of scans: 30 scans

Exposure time: auto

Temperature measurement range: 30 to 200° C.

Temperature measurement step: 10° C.

Excitation wavelength range: +/−20 nm

Phosphor wavelength range: 370 to 800 nm

The obtained wavelength conversion filter was subjected to an accelerated deterioration test. The accelerated deterioration test was a test in which the wavelength conversion filter was left at 80° C. for five hours in a constant-temperature oven. The wavelength conversion filter having been subjected to the accelerated deterioration test was measured in terms of the external quantum efficiency and absorptance in the same way as that described above.

The values of the external quantum efficiency and absorptance measured after the accelerated deterioration test were respectively divided by the values of the external quantum efficiency and absorptance measured before the accelerated deterioration test to calculate retentions (%) of the external quantum efficiency and absorptance. The results thereof are shown in Table 1.

TABLE 1

| | Retention of | |
|---|---|---|
| | External Quantum | Retention of |
| | Efficiency (%) | Absorptance (%) |
| Example 1 | 99< | 99< |
| Example 2 | 99< | 99< |
| Example 3 | 99< | 99< |
| Example 4 | 99< | 99< |
| Example 5 | 99< | 99< |
| Example 6 | 99< | 99< |
| Comparative | 74 | 99< |
| Example 1 | | |

### Example 2

### (Wavelength Conversion Filter)

[Wavelength Conversion Layer]

The same wavelength conversion layer as Example 1 was used.

[Ultraviolet Absorption Layer]

0.012 parts by mass of RUVA-93 (made by Otsuka Chemical Co., Ltd.) as the organic reactive ultraviolet absorber and 100 parts by mass of EVA (EVAFLEX (registered trademark) EV530 made by DU-PONT MITSUI POLYCHEMICALS) were prepared. Moreover, 0.3 parts by mass of Trigonox (registered trademark) 17 made by Kayaku Akzo Corporation was prepared as the polymerizer. The 0.012 parts by mass of RUVA-93, the 100 parts by mass of EVA, and the 0.3 parts by mass of Trigonox 17 were melted and kneaded with a plastomill (made by TOYO SEIKI Co., Ltd.) at a heating temperature of 150° C. at 30 rpm for 30 minutes. RUVA-93 includes the ultraviolet absorption part of the benzotriazole structure. The kneaded product was heat-pressed into a sheet with a thickness of 0.6 mm, thus preparing the ultraviolet absorption layer.

[Fusion of Wavelength Conversion Layer and Ultraviolet Absorption Layer]

Similarly to Example 1, the wavelength conversion layer and ultraviolet absorption layer were thermally fused into the wavelength conversion filter.

### (Measurement of External Quantum Efficiency and Absorptance)

The obtained wavelength conversion filter was measured in terms of the retention (%) of the external quantum efficiency and the retention (%) of the absorptance in a similar manner to Example 1. The results are shown in Table 1.

### Example 3

### (Wavelength Conversion Filter)

[Wavelength Conversion Layer]

The same wavelength conversion layer as Example 1 was used.

[Ultraviolet Absorption Layer]

0.1 parts by mass (in zinc oxide nanoparticles) of zinc oxide nanoparticle dispersion NANOBYK (registered trademark) -3841 (made by BYK K. K.) as the inorganic ultraviolet absorber and 100 parts by mass of EVA (EVAFLEX (registered trademark) EV450 made by DU-PONT MITSUI POLYCHEMICALS) were prepared. These materials were melted and kneaded with a plastomill (made by TOYO SEIKI Co., Ltd.) at a heating temperature of 150° C. at 30 rpm for 30 minutes. The kneaded product was heat-pressed into a sheet with a thickness of 0.6 mm, thus preparing the ultraviolet absorption layer.

[Fusion of Wavelength Conversion Layer and Ultraviolet Absorption Layer]

Similarly to Example 1, the wavelength conversion layer and ultraviolet absorption layer were thermally fused into the wavelength conversion filter.

### (Measurement of External Quantum Efficiency and Absorptance)

The obtained wavelength conversion filter was measured in terms of the retention (%) of the external quantum efficiency and the retention (%) of the absorptance in a similar manner to Example 1. The results are shown in Table 1.

### Example 4

[Wavelength Conversion Layer]

0.02 parts by mass of Lumogen (registered trademark) F violet 570 (made by BASF SE) as the organic phosphor and 100 parts by mass of EVA (EVAFLEX (registered trademark) EV450 made by DU-PONT MITSUI POLYCHEMICALS) were prepared. These materials were melted and kneaded with a plastomill (made by TOYO SEIKI Co., Ltd.) at a heating temperature of 150° C. at 30 rpm for 30 minutes. The kneaded product was heat-pressed into a sheet with a thickness of 0.6 mm, thus preparing the ultraviolet absorption layer.

[Ultraviolet Absorption Layer]

The same ultraviolet absorption layer as Example 2 was used.

[Fusion of Wavelength Conversion Layer and Ultraviolet Absorption Layer]

Similarly to Example 1, the wavelength conversion layer and ultraviolet absorption layer were thermally fused into the wavelength conversion filter.

### (Measurement of External Quantum Efficiency and Absorptance)

The obtained wavelength conversion filter was measured in terms of the retention (%) of the external quantum efficiency and the retention (%) of the absorptance in a similar manner to Example 1. The results are shown in Table 1.

### Example 5

[Wavelength Conversion Layer]

The same wavelength conversion layer as Example 4 was used.

[Ultraviolet Absorption Layer]

0.012 parts by mass of RUVA-93 (made by Otsuka Chemical Co., Ltd.) as the organic reactive ultraviolet absorber and 100 parts by mass of EVA (EVAFLEX (registered trademark) EV530 made by DU-PONT MITSUI POLYCHEMICALS) were prepared. Moreover, 3 parts by mass of TMPT (made by Shin-Nakamura Chemical Co., Ltd.) as the cross-linking agent and 0.3 parts by mass of Trigonox (registered trademark) 17 made by Kayaku Akzo Corporation as the polymerizer were prepared. The 0.012 parts by mass of RUVA-93, the 100 parts by mass of EVA, the 3 parts by mass of TMPT, and the 0.3 parts by mass of Trigonox 17 were melted and kneaded with a plastomill (made by TOYO SEIKI Co., Ltd.) at a heating temperature of 150° C. at 30 rpm for 30 minutes. The kneaded product was heat-pressed into a sheet with a thickness of 0.6 mm, thus preparing the ultraviolet absorption layer.

[Fusion of Wavelength Conversion Layer and Ultraviolet Absorption Layer]

Similarly to Example 1, the wavelength conversion layer and ultraviolet absorption layer were thermally fused into the wavelength conversion filter.

### (Measurement of External Quantum Efficiency and Absorptance)

The obtained wavelength conversion filter was measured in terms of the retention (%) of the external quantum efficiency and the retention (%) of the absorptance in a similar manner to Example 1. The results are shown in Table 1.

### Example 6

[Wavelength Conversion Layer]

The same wavelength conversion layer as Example 4 was used.

[Ultraviolet Absorption Layer]

0.012 parts by mass of RUVA-93 (made by Otsuka Chemical Co., Ltd.) as the organic reactive ultraviolet absorber and 100 parts by mass of olefin sealing material (Tafmer (registered trademark) P0275 made by Mitsui Chemicals Inc.) were prepared. Moreover, 3 parts by mass of TMPT (made by Shin-Nakamura Chemical Co., Ltd.) as the cross-linking agent and 0.3 parts by mass of Trigonox (registered trademark) 17 made by Kayaku Akzo Corporation as the polymerizer were prepared. The 0.012 parts by mass of RUVA-93, the 100 parts by mass of the olefin sealing material, the 3 parts by mass of TMPT, and the 0.3 parts by mass of Trigonox 17 were melted and kneaded with a plastomill (made by TOYO SEIKI Co., Ltd.) at a heating temperature of 150° C. at 30 rpm for 30 minutes. The kneaded product was heat-pressed into a sheet with a thickness of 0.6 mm, thus preparing the ultraviolet absorption layer.

[Fusion of Wavelength Conversion Layer and Ultraviolet Absorption Layer]

Similarly to Example 1, the wavelength conversion layer and ultraviolet absorption layer were thermally fused into the wavelength conversion filter.

### (Measurement of External Quantum Efficiency and Absorptance)

The obtained wavelength conversion filter was measured in terms of the retention (%) of the external quantum efficiency and the retention (%) of the absorptance in a similar manner to Example 1. The results are shown in Table 1.

### Comparative Example 1

### (Wavelength Conversion Filter)

[Wavelength Conversion Layer]

The same wavelength conversion layer as Example 1 was used.

[Ultraviolet Absorption Layer]

0.012 parts by mass of Tinuvin (registered trademark, made by BASF SE) P (molecular weight: 225) as the organic reactive ultraviolet absorber and 100 parts by mass of EVA (EVAFLEX (registered trademark) EV450 made by DU-PONT MITSUI POLYCHEMICALS) were prepared. These materials were melted and kneaded with a plastomill (made by TOYO SEIKI Co., Ltd.) at a heating temperature of 150° C. at 30 rpm for 30 minutes. Tinuvin (registered trademark) P includes the ultraviolet absorption part of the benzotriazole structure but has a small molecular weight of 225. The kneaded product was heat-pressed into a sheet with a thickness of 0.6 mm, thus preparing the ultraviolet absorption layer.

[Fusion of Wavelength Conversion Layer and Ultraviolet Absorption Layer]

Similarly to Example 1, the wavelength conversion layer and ultraviolet absorption layer were thermally fused into the wavelength conversion filter.

### (Measurement of External Quantum Efficiency and Absorptance)

The obtained wavelength conversion filter was measured in terms of the retention (%) of the external quantum efficiency and the retention (%) of the absorptance in a similar manner to Example 1. The results are shown in Table 1.

In the wavelength conversion filter after the accelerated deterioration test, Tinuvin (registered trademark) P in the ultraviolet absorption layer 40 was not be incorporated in the molecular backbone of EVA as the transparent resin base material 41 and diffused in the wavelength conversion layer 30. In the wavelength conversion filter 20 after the accelerated deterioration test, the boundary between the wavelength conversion layer 30 and ultraviolet absorption layer 40 was not clear, and the two-layer structure of the wavelength conversion layer 30 and ultraviolet absorption layer 40 was not maintained.

### Comparison between Examples 1 to 6 and Comparative Example 1

Table 1 has confirmed that the external quantum efficiency of Examples 1 to 6 was retained to 90% or more after the evaluation. On the other hand, the external quantum efficiency of Comparative Example 1, which used the ultraviolet absorber having a low molecular weight, was significantly reduced.

The entire contents of Japanese Patent Application No. 2015-161880 (filed on 19 Aug. 2015) and Japanese Patent Application No. 2016-047729 (filed on 11 Mar. 2016) are incorporated herein by reference.

Hereinabove, the embodiment is described along the examples but is not limited to the description thereof. It is obvious to those skilled in the art that various modifications and improvements can be made for the embodiment.

### INDUSTRIAL APPLICABILITY

According to the wavelength conversion filter of the invention, high efficiency of wavelength conversion from ultraviolet light to visible light is maintained in the long term. According to the method of manufacturing the wavelength conversion filter of the present invention, it is possible to manufacture the wavelength conversion filter able to maintain high efficiency of wavelength conversion from ultraviolet light to visible light for a long time. According to the solar cell module of the present invention, high efficiency of wavelength conversion from ultraviolet light to visible light is maintained in the long term.

### REFERENCE SIGNS LIST

1 SOLAR CELL MODULE

20 WAVELENGTH CONVERSION FILTER

30 WAVELENGTH CONVERSION LAYER

31, 41 TRANSPARENT RESIN BASE MATERIAL

35 PHOSPHOR (WAVELENGTH CONVERSION MATERIAL)

40 ULTRAVIOLET ABSORPTION LAYER

45 ULTRAVIOLET ABSORBER (REACTIVE ULTRAVIOLET ABSORBER, STABLE UNREACTIVE ABSORBER)

1. A wavelength conversion filter, comprising:
a wavelength conversion layer in which a wavelength conversion material is dispersed in a transparent resin base material; and
an ultraviolet absorption layer which is provided on the surface of the wavelength conversion layer and in which an ultraviolet absorber is dispersed in a transparent resin base material, wherein
the wavelength conversion layer contains 0.01 to 30 parts by mass of the wavelength conversion material with respect to 100 parts by mass of the transparent resin base material included in the wavelength conversion layer.

2. The wavelength conversion filter according to claim 1, wherein the ultraviolet absorber is an inorganic ultraviolet absorber.

3. The wavelength conversion filter according to claim 1, wherein the ultraviolet absorber is a reactive ultraviolet absorber which includes an ultraviolet absorption part having a molecular structure for absorbing ultraviolet light and has a function of combining with a molecular backbone of the transparent resin base material included in the ultraviolet absorption layer.

4. The wavelength conversion filter according to claim 1, wherein the reactive ultraviolet absorber combines with the molecular backbone of the transparent resin base material included in the ultraviolet absorption layer to be incorporated in the molecular backbone of the transparent resin base material.

5. The wavelength conversion filter according to claim 1, wherein the ultraviolet absorption part of the reactive ultraviolet absorber includes one or more types of structure selected from a group consisting of a benzotriazole structure, a triazine structure, and a benzophenone structure.

6. The wavelength conversion filter according to claim 1, wherein the ultraviolet absorber is an unreactive ultraviolet absorber which includes the molecular backbone of the transparent resin and an ultraviolet absorption part having a molecular structure for combining with the molecular backbone and absorbing ultraviolet light.

7. The wavelength conversion filter according to claim 1, wherein the molecular weight of the unreactive ultraviolet absorber is not less than 5000.

8. The wavelength conversion filter according to claim 1, wherein the ultraviolet absorption part of the unreactive ultraviolet absorber includes one or more types of structure selected from a group consisting of a benzotriazole structure, a triazine structure, and a benzophenone structure.

9. A solar cell module, comprising:
a wavelength conversion filter according to claim 1;
a surface protection sheet which is provided on the side of the wavelength conversion layer constituting the wavelength conversion filter; and
a solar cell which is provided on the side of the ultraviolet absorption layer constituting the wavelength conversion filter and generates electric power with visible light having passed through the wavelength conversion filter.

10. A method of manufacturing a wavelength conversion filter according to claim 1, the method comprising:
combining the reactive ultraviolet absorber with the molecular backbone of the transparent resin base material included in the ultraviolet absorption layer to form an ultraviolet absorber of the same or similar structure to that of an unreactive ultraviolet absorber.
